(19) United States
(12) Patent Application Publication
(10) Pub. No.: US 2025/0258213 A1
(43) Pub. Date: Aug. 14, 2025

(54) DIE CRACK DETECTION SYSTEM

(71) Applicant: Ampleon Netherlands B.V., Nijmegen (NL)

(72) Inventors: Mariano Ercoli, Nijmegen (NL); Stephan Maroldt, Nijmegen (NL); Bart Van Velzen, Nijmegen (NL)

(21) Appl. No.: 19/047,803

(22) Filed: Feb. 7, 2025

(30) Foreign Application Priority Data
Feb. 8, 2024 (NL) 2036992

(51) Int. Cl. G01R 31/26

(52) U.S. Cl. CPC G01R 31/2621

(57) ABSTRACT

Example embodiments relate to die crack detection systems. An example die crack detection system includes a semiconductor device and a measuring unit. The semiconductor device includes a semiconductor body in or on which at least one component is integrated and that comprises a conductive region. The semiconductor device also includes an electrically insulating layer arranged on the conductive region. Additionally, the semiconductor device includes a first conductive trace arranged on the electrically insulating layer. Further, the semiconductor device includes a first contact that is electrically connected to the first conductive trace. In addition, the semiconductor device includes a second contact that is electrically connected to the conductive region. The first conductive trace, the electrically insulating layer, and the conductive region form a capacitor. The first contact is arranged at an end of the first conductive trace. The first conductive trace includes a fifth contact.

### CROSS-REFERENCE TO RELATED APPLICATIONS

The present application is a non-provisional patent application claiming priority to Netherlands Patent Application No. NL 2036992, filed Feb. 8, 2024, the contents of which are hereby incorporated by reference.

### FIELD OF THE DISCLOSURE

The present disclosure relates to a die crack detection system. The present disclosure further relates to a semiconductor device suitable to be used in such die crack detection system.

### BACKGROUND

Semiconductor products are often produced using semiconductor wafers. On these wafers, a plurality of identical components or circuits is realized. By dicing the semiconductor wafer, a plurality of substantially identical semiconductor dies is obtained, wherein each semiconductor die comprises a respective component or circuit.

Typically, for manufacturing a semiconductor die, a large plurality of processing steps is required including a dicing step. As a result of these steps, the semiconductor die may become damaged. An example of such damage is the formation of a crack in the semiconductor die. Such crack may result in unwanted electrical behavior of the component or circuit that is formed on such die.

Several solutions are known for detecting a crack in the semiconductor die. A first example, disclosed in U.S. Pat. No. 10,241,151B2, comprises the use of metal traces separated by a thin dielectric layer. In case of a die crack, the dielectric layer would become damaged, and the capacitance measured between the metal traces would show signs of leakage.

### SUMMARY

Detecting cracks may be performed on semiconductor wafer level or on semiconductor die level. Hereinafter, both a semiconductor wafer and a semiconductor die are referred to as a semiconductor body.

Some electrical components benefit from having relatively thin semiconductor substrates. An example of such component is a power amplifier, wherein substrate thickness is associated with parasitic inductance and/or thermal resistance.

Semiconductor substrates that are relatively thin are more prone to cracking. Additionally, compared to thicker substrates, some of these cracks may be smaller in size. Some of these cracks are known as micro-cracks and may have widths in a range between 1 and 10 nanometer, a length between a few micrometers up to 1000 micrometer, and a depth between few micrometers up to the entire thickness of the die.

The Applicant has found that micro-cracks cannot be detected with existing die crack detection methods with sufficient accuracy and/or convenience.

Example embodiments provide a die crack detection system with which micro-cracks can be readily detected.

This may be achieved using a die crack detection system that comprises a semiconductor device having a semiconductor body in or on which at least one component is integrated and that comprises a conductive region. Such conductive region may be formed during growth of the semiconductor body or may have been formed using ion implantation.

The semiconductor device further comprises an electrically insulating layer arranged on the conductive region, a first conductive trace arranged on the electrically insulating layer, a first contact that is electrically connected to the first conductive trace, and a second contact that is electrically connected to the conductive region.

The die crack detection system further comprises a measuring unit. The first conductive trace, the electrically insulating layer, and the conductive region form a capacitor. Furthermore, the die crack detection system is operable in a first mode in which mode the measuring unit is configured to output a first electrical signal to the first contact and/or second contact, and to determine whether at least one die crack exists in the semiconductor body based on I-V characteristics corresponding to the outputted first electrical signal.

In some embodiments, a capacitor is formed between the conductive region and the first conductive trace. Because the conductive region, which is part of the semiconductor body, is used as one of the plates/terminals of the capacitor, the capacitor is more sensitive to cracks in the semiconductor body and is therefore suitable for detecting micro-cracks in the semiconductor body.

The second contact can be configured to be electrically grounded when operating in the first mode. In this case, the first electrical signal can be a current through the first contact or a voltage applied to the first contact. In other embodiments, the first electrical signal is a differential signal. For example, the first electrical signal may comprise a voltage v1 applied to the first contact and a voltage −v1 applied to the second contact.

The first electrical signal can be a voltage signal and the measuring unit can be configured to determine that at least one die crack exists when a current through the first contact and/or second contact exceeds a first threshold. In case of a die crack, the electrically insulating layer may become damaged and a leakage path between the conductive region and the first conductive trace is formed. Example embodiments are not limited to a single electrically insulating layer arranged in between the conductive region and the first conductive region. Rather, a plurality of electrically insulating layers, optionally separated by electrically floating plates, may be used.

The measuring unit can be configured to measure the current through the first contact and/or second contact a predetermined amount of time after applying the voltage signal to avoid or limit measuring a current that is associated with charging a capacitance formed between the first conductive trace and the conductive region. A leaky capacitor can be represented by a parallel connection of an ideal capacitor and a non-zero resistance. Upon applying the voltage signal, a relatively large current will flow through the ideal capacitor. After some time, the voltage over the ideal capacitor will be the same as the voltage signal assuming that the voltage signal is a slowly varying signal or a step signal. Measuring the current after the voltage over the capacitor has settled provides more accurate information on the presence or absence of a die crack. More in particular, a relatively high current is associated with a die crack, and a relatively low current is associated with no die crack.

The at least one component can be a metal-oxide-semiconductor field-effect transistor, MOSFET, a metal-insulator-semiconductor field-effect transistor, MISFET, or metal-insulator-metal capacitor. The semiconductor body may comprise a Silicon substrate and the at least one component may comprise a laterally diffused metal-oxide-semiconductor, LDMOS, field-effect transistor.

The electrically insulating layer can be formed by an electrically insulating layer that is also arranged in between a gate and the semiconductor body of the MOSFET or MISFET, or can be formed by the insulator of the metal-insulator-metal capacitor.

A thickness of the electrically insulating layer may lie in a range between 2 nm and 200 nm. The electrically insulating layer can be made of silicon oxide, silicon dioxide, silicon nitride, or silicon oxynitride. Furthermore, a width of the first conductive trace may lie within a range from 0.1 to 50 micrometer, more preferably within a range from 1 to 10 micrometer, and the first conductive trace can be made from polysilicon and/or metal.

The die crack detection system may further comprise a second conductive trace, the second conductive trace having a third contact and a fourth contact arranged on opposite ends of the second conductive trace. In this case, the die crack detection system can further be operable in a second mode. The measuring unit can be configured to, when the die crack detection system operates in the second mode, output a second electrical signal to the third contact and/or fourth contact, and to determine whether at least one die crack exists in the semiconductor body based on I-V characteristics corresponding to the outputted second electrical signal.

Similar to the first electrical signal, the fourth contact can be configured to be electrically grounded when operating in the second mode. In this case, the second electrical signal can be a current through the third contact or a voltage applied to the third contact. In other embodiments, the second electrical signal is a differential signal. For example, the second electrical signal may comprise a voltage v2 applied to the third contact and a voltage −v2 applied to the fourth contact.

The second electrical signal can be a voltage signal, and the measuring unit can be configured to determine, when the die crack detection system operates in the second mode, that at least one die crack exists when a current through the third contact and/or fourth contact is below a second threshold.

The measuring unit can be configured to measure the current through the third contact and/or fourth contact a predetermined amount of time after applying the voltage signal to avoid or limit measuring a current that is associated with charging a capacitance formed between the second conductive trace and the conductive region. The second conductive trace can be represented by a ladder network comprising shunt capacitors and series resistors. In case of a die crack at the position of the second conductive trace, a very high series resistance will result. Consequently, a relatively high current is associated with no die crack, and a relatively low current is associated with a die crack.

The die crack detection system can further be operable in a third mode, wherein the measuring unit is configured to, when the die crack detection system operates in the third mode, output a third electrical signal to the first and/or second contacts, and output a fourth electrical signal to the third and/or fourth contacts, and to determine whether at least one die crack exists in the semiconductor body based on I-V characteristics corresponding to the outputted third electrical signal and associated with the first and second electrical contacts and based on I-V characteristics corresponding to the outputted fourth electrical signal and associated with the third and fourth electrical contacts.

The second conductive trace may form an elongated resistor, such as a thin film resistor, wherein the second conductive trace is preferably made from a metal, for example from one or more materials from the group consisting of Ti, TiN, and W. The sheet resistance of the second conductive trace may lie in a range between 0.1 and 50 Ohm per square, more preferably between 1 and 10 Ohm per square, even more preferably between 1 and 5 Ohm per square, and a width of the second conductive trace may lie within a range from 0.1 to 50 micrometer, more preferably within a range from 1 to 10 micrometer. The second conductive trace may be arranged directly above the first conductive trace. The length of the first and second traces is adaptable to the configuration of the circuit.

The first contact may be arranged at an end of the first conductive trace. The first conductive trace may further comprise a fifth contact arranged at an opposing end of the first conductive trace. The first and fifth contacts may be configured to be contacted by a measuring probe or other electrical connection of the measuring unit.

A shape of the second conductive trace can be identical to a shape of the first conductive trace. This allows the first conductive trace and the second conductive trace to be formed as a combined path. This is advantageous when designing the semiconductor device, circuit or component. For example, a user may draw a single path on the CAD system as a result of which a first and second conductive trace are simultaneously drawn. In addition, the first and third contacts may form a first unit, and the fourth and fifth contacts may form a second unit. These units can be inserted after having drawn the path. In other embodiments, when drawing a path, a first unit may be automatically drawn and after having finished the path, a second unit may be automatically drawn. Furthermore, the first unit can be identical to the second unit.

The first unit and the second unit may each comprise a contact pad, a first trace contact part that is electrically connected to the first conductive trace, a second trace contact part that is electrically connected to the second conductive trace, and at least one of a) one or more first vias connecting the first trace contact part to the contact pad, b) one or more second vias connecting the second trace contact part to the contact pad, and c) one or more ground vias connecting the contact pad, at least during operation, to ground.

During the design phase, a user may draw a path and then connect the end(s) to a first unit or second unit. Here, it is noted that the first unit and the second unit may be different embodiments or the same embodiment of a generic unit. This generic unit can be adapted by the user, by means of selecting which vias to use, for forming the first unit and second unit. For example, when designing the first unit, the user may be presented with the option to implement any one or more of the abovementioned vias. When only the first vias are selected, the contact pad is only connected to the first conductive trace. When only the second vias are selected, the contact is only connected to the second conductive trace. If one or more ground vias are used, the contact pad can be grounded during operation. In these cases, if a first and/or second via is used, the corresponding first and/or second traces are connected to ground.

The semiconductor body may comprise a substrate on which an epitaxial layer is arranged, wherein the conductive region is formed within the epitaxial layer. The epitaxial layer may comprise one or more sublayers. The conductive region can be formed in one or a plurality of these sublayers by means of ion implantation. Alternatively, the conductive region may be formed during growth of the epitaxial layer or the one or more sublayers thereof. The second contact can be formed on and/or by a backside of the substrate.

Grounding of the conductive region can be obtained in various manners. For example, the conductive region can be connected to a backside of the semiconductor substrate and therefor to the second contact using one or more vias. In other embodiments, the substrate can be a conductive substrate and the epitaxial layer can be electrically connected to the conductive substrate. In this case, when the die crack detection system operates in the first mode, electrical grounding of the conductive region can be effectuated through the conductive substrate.

A thickness of the semiconductor body may lie within a range from 25 to 1000 micrometer, more preferably between 50 and 500 micrometer.

In some embodiments, the measuring unit is arranged outside of the semiconductor body. For example, the measuring unit may be a separate device having measuring probes for contacting the first, second, third, fourth, and/or fifth contacts. Alternatively, for some embodiments, the measuring unit can be integrated in the semiconductor body. In such case, the measuring unit may have an input terminal for receiving a control signal for enabling the die crack detection system to operate in the first mode, the second mode, or the third mode, and may have an output terminal for outputting a signal indicative for whether the measuring unit has determined that at least one die crack in the semiconductor body exists or not.

According to a second aspect, example embodiments provide a semiconductor device configured as the semiconductor device defined above.

### BRIEF DESCRIPTION OF THE DRAWINGS

Next, example embodiments will be described referring to the appended DRAWINGS

FIG. 1A is an illustration of a LDMOS transistor, according to example embodiments.

FIG. 1B is an illustration of a MISFET, according to example embodiments.

FIG. 1C is an illustration of a semiconductor device, according to example embodiments.

FIG. 2A is an illustration of a semiconductor device, according to example embodiments.

FIG. 2B is an illustration of a semiconductor device, according to example embodiments.

FIG. 3 is an illustration of a semiconductor device, according to example embodiments.

FIG. 4 is an illustration of units of a die crack detection system, according to example embodiments.

FIG. 5A is an illustration of a first unit, according to example embodiments.

FIG. 5B is an illustration of a first unit, according to example embodiments.

FIG. 5C is an illustration of a first unit, according to example embodiments.

FIG. 6 is an illustration of a semiconductor die, according to example embodiments.

### DETAILED DESCRIPTION

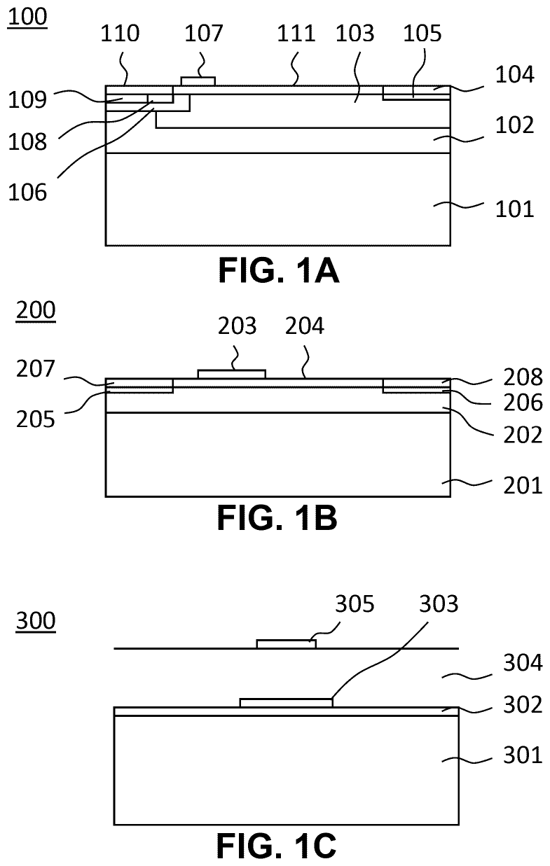

FIG. 1A illustrates an example of a Silicon LDMOS transistor 100 comprising a p-type Silicon substrate 101 on which a p-type epitaxial layer 102 has been grown. Inside layer 102, an n-type drift region 103 is formed. Contact to this layer is made possible using a drain contact 104 that is arranged above a highly n-type doped drain contact region 105 formed inside drift region 103.

A p-type body 106 is formed inside layer 102 that extends underneath polysilicon gate contact 107. Inside body 106 an n-type source region 108 and a p-type region 109 is formed. Optionally, a source contact 110 is provided that is arranged above source regions 108, 109.

In between gate contact 107 and epitaxial layer 102, a gate oxide layer 111 is present. Oxide layer 111 can also be used for the formation of a capacitor of the die crack detection system, according to example embodiments.

FIG. 1B illustrates an example of a Gallium Nitride MISFET 200 comprising a GaN substrate 201, which may itself be arranged on a sapphire or SiC substrate. An n-type AlGaN layer 202 is arranged on GaN substrate 201. At the heterojunction between layers 201, 202 a two-dimensional electron gas, 2DEG, is formed. The electron concentration inside this 2DEG can be controlled using gate contact 203. An insulating layer 204, such as silicon nitride, is arranged in between gate contact 203 and AlGaN layer 202.

Inside AlGaN layer highly n-type doped contact regions 205, 206 are provided for enabling low Ohmic contact resistance with a source contact 207 and drain contact 208, respectively.

Similar to gate oxide 111, insulating layer 204 can also be used for the formation of a capacitor of the die crack detection system, according to example embodiments.

FIG. 1C illustrates a cross section of a semiconductor device 300 that is suitable to be used in a die crack detection system, according to example embodiments. It comprises a semiconductor body 301 on which an insulating layer 302 is arranged. On top of insulating layer 302, a conductive trace 303 is arranged. Furthermore, one or more dielectric layers 304 are provided over conductive trace 303. These dielectric layers are part of a metal layer stack in which stack further conductive traces are formed albeit with a higher thickness than trace 303. On one or more of the dielectric layers, a thin layer 305 of resistive material is deposited for forming a thin film resistor.

Semiconductor device 300 may relate to MISFET 200 or LDMOS transistor 100. For example, trace 303 may be formed using the same layer(s) and simultaneously with gate contact 203 or gate contact 107. In addition, semiconductor body 301 may correspond to the combination of substrate 101 and epitaxial layer 102, or the combination of GaN substrate 201 and AlGaN layer 202. Insulation layer 302 may be formed using the same layer(s) and simultaneously with gate oxide 111 and insulating layer 204.

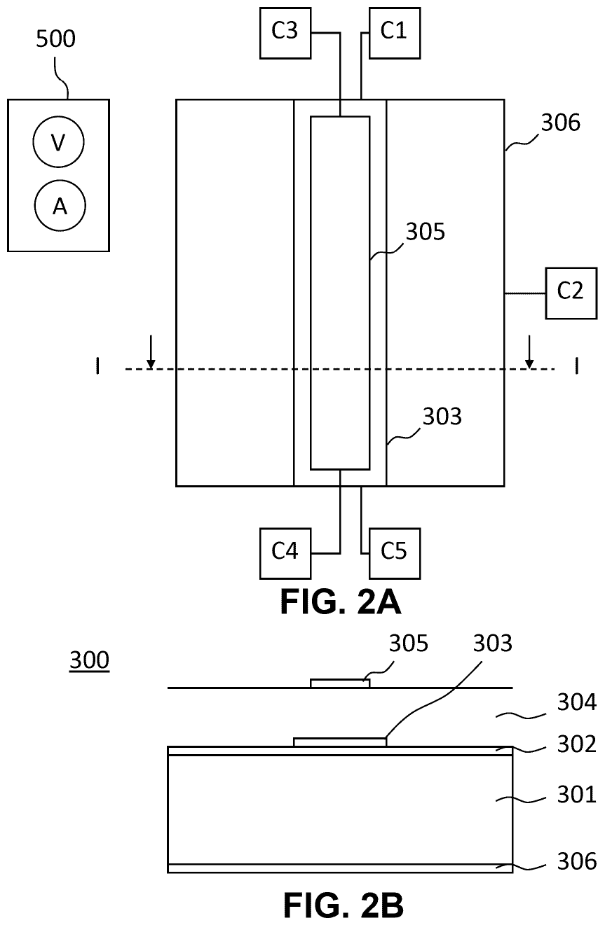

FIG. 2A schematically illustrates a top view of semiconductor device 300 that can be used as a die crack detection system according to example embodiments, wherein dashed line I-I corresponds to the cross section shown in FIG. 2B. Furthermore, in device 300, a separate contact 306 is provided at the backside of semiconductor body 301. In FIG. 2A, a first contact C1 and a fifth contact C5 are electrically connected to trace 303, and a third contact C3 and fourth contact C4 are connected to trace 305. A second contact C2 corresponds to contact 306.

FIG. 2A further schematically illustrates a measurement unit 500 that is capable of providing an electrical signal, such as a current or voltage, to any one or more of contacts C1-C5. Furthermore, measurement unit 500 is further capable of measuring a voltage at and/or a current through any one or more of contacts C1-C5.

The die crack detection system of FIGS. 2A and 2B is operable in three modes. In a first mode, only trace 303 is used for detecting cracks. This measurement is based on the IV characteristics of a shunt capacitor between C2 and any of C1 and C5. In the table below, examples of this mode are provided. Here, #n indicates the signal applied to contact Cn, wherein V1 indicates a voltage V1, GND a ground reference voltage, and wherein NC indicates that the corresponding contact is not connected. Furthermore, I(n) indicates a measurement of the current through contact n.

| Mode | #1 | #2 | #3 | #4 | #5 | Measurement |
|---|---|---|---|---|---|---|
| 1 | V1 | GND | NC | NC | NC | I(1) or I(2) |
| 1 | NC | V1 | NC | NC | GND | I(2) or I(5) |
| 1 | V1 | GND | NC | NC | V1 | I(1) and I(5), |
| | | | | | | or I(2) |

In a second mode, only trace 305 is used for detecting cracks. This measurement is based on the IV characteristics of a series resistor between the third and fourth contacts. In the table below, examples of this mode are provided.

| Mode | #1 | #2 | #3 | #4 | #5 | Measurement |
|---|---|---|---|---|---|---|
| 2 | NC | NC | V1 | GND | NC | I(3) or I(4) |
| 2 | NC | NC | +V1 | −V1 | NC | I(3) or I(4) |

In a third mode, both trace 303 and trace 305 are used for detecting cracks. In the table below, examples of this mode are provided.

| Mode | #1 | #2 | #3 | #4 | #5 | Measurement |
|---|---|---|---|---|---|---|
| 3 | V1 | GND | V2 | GND | NC | (I(3) or I(4)) |
| | | | | | | and (I(1) or |
| | | | | | | I(2)) |
| 3 | V1 | GND | +V2 | -V2 | V1 | (I(3) or I(4) |
| | | | | | | and (I(1), |
| | | | | | | I(2), I(5) |

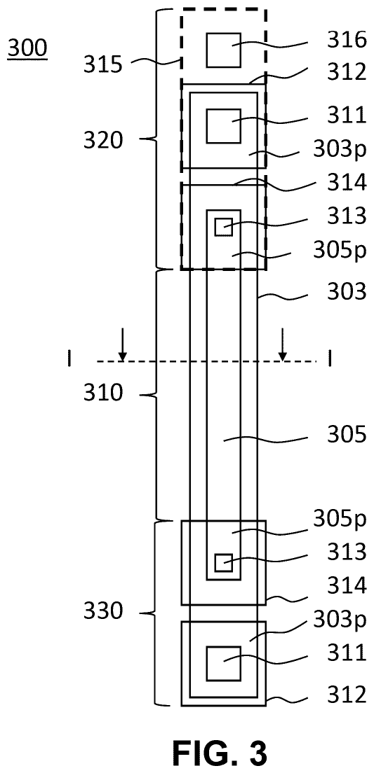

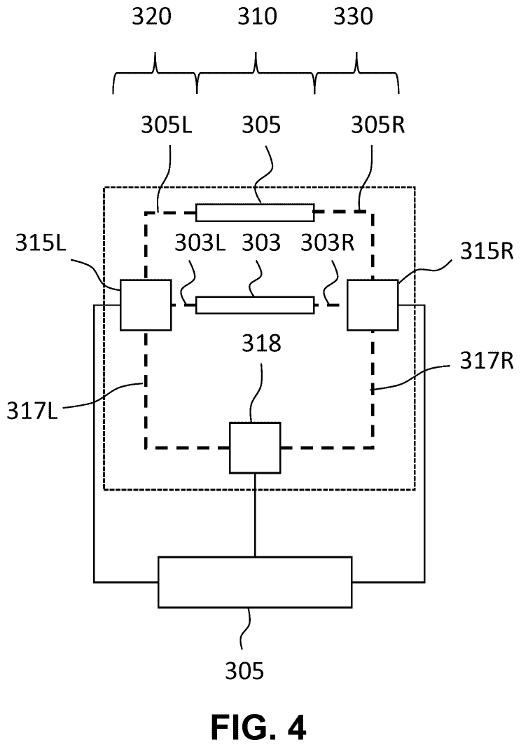

The abovementioned list of examples of the various modes is not exhaustive. Furthermore, in the abovementioned examples, the first and third contact, and the fourth and fifth contacts are distinct contacts. This allows separate signals to be applied, at the same time, to the first and third contacts for example. In this manner, a die crack can be detected using traces 303, 305 simultaneously. In other embodiments, these measurements are to be performed sequentially. In that case, it may be possible to electrically connect the first and third contacts, and the fourth and fifth contacts. For example, these contacts can be formed or connected to a single conductive pad. Examples of such embodiments are shown in FIGS. 3 and 4.

FIG. 3 illustrates a top view of semiconductor device 300, wherein dashed line I-I corresponds to the cross section of FIG. 1C. Semiconductor device 300 comprises traces 303, 305 which in FIG. 3 are combined as a path 310. More in particular, trace 305 lies above trace 303. When designing a circuit that should be provided with a die crack detection system, path 310 can be drawn as a component using the CAD system. After having drawn path 310, contacts to the path should be provided. To this end, a first unit 320 and second unit 330 are provided on opposite sides of path 310. In some embodiments, one of units 320, 330 is omitted.

First unit 320 and second unit 330 each comprise a piece 303p of trace 303 to connect to trace 303 of path 310, and a piece 305p of trace 305 to connect to trace 305 of path 310. Furthermore, units 320, 330 each comprise one or more vias 311 for connecting piece 303p to a pad 312 formed in a relatively thick metal layer, and one or more vias 313 for connecting piece 305p to pad 314 also formed in a relatively thick metal layer. Pads 312 and 314 allow electrical contact to be made to traces 303, 305, respectively, for applying the electrical signals for die crack detection.

In the embodiment of the die crack detection system shown in FIG. 3, pads 312, 314 of first unit 320 are interconnected to form a pad 315. For second unit 330 of this semiconductor device, such interconnection is not made. Furthermore, pad 315 is connected to ground through one or more further vias 316. Connection to ground can for example be made using vias that extend into the semiconductor body up to a layer that is electrically grounded during operation. Alternatively, a ground connection could be realized in different ways for example by providing a dedicated contact in the form of a lead or other terminal that is electrically grounded during operation.

FIG. 4 illustrates a schematic representation of units 320, 330 of the die crack detection system according to example embodiments in which pads 312, 314 are interconnected to form a pad 315L, 315R, respectively. Furthermore, a separate contact 318 is provided at the backside of the semiconductor body.

Dashed lines 303L, 305L illustrate the electrical connection between traces 303, 305, and pad 315L, respectively, dashed lines 303R, 305R the electrical connection between traces 303, 305, and pad 315R, respectively, and dashed lines 317L, 317R, the electrical connection between pads 315L, 315R, and a central ground pad 318.

Dashed lines 303L, 305L, 303R, 305R, 317L, and 317R indicate that the corresponding connections are optional.

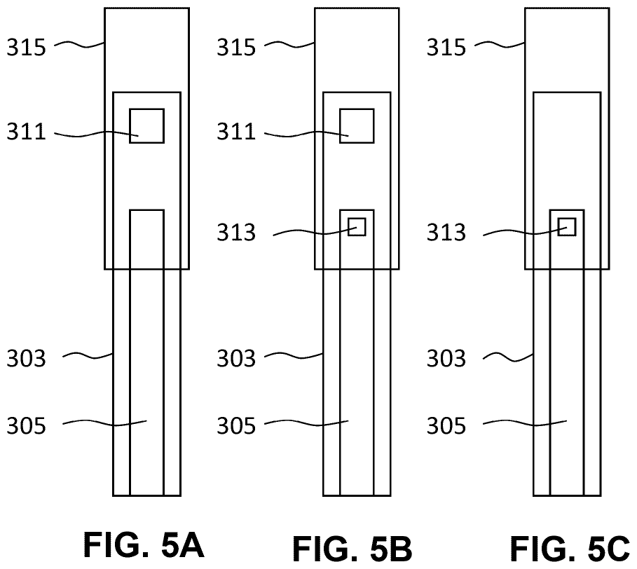

FIGS. 5A-5C illustrate various other examples of a first unit, according to example embodiments. In the first unit of FIG. 5A, only trace 303 is connected to pad 315. In the first unit of FIG. 5B, traces 303 and 305 are both connected to pad 315, whereas in the first unit of FIG. 5C, only trace 305 is connected to pad 315.

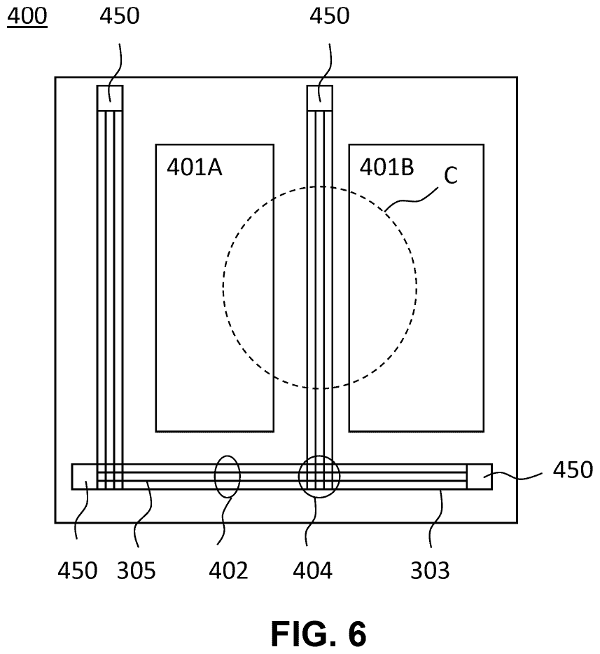

FIG. 6 illustrates a semiconductor die 400 in which the die crack detection system according to example embodiments is implemented. Semiconductor die 400 comprises circuits 401A, 401B and a plurality of paths 402 that are each configured as path 310 in FIG. 3. At intersections 404, two or more paths come together. At intersections 404, traces 303 and traces 305 of the various paths are physically connected to each other. At the various ends, units 450 are provided for enabling electrical signals to be applied. These units are configured similar to units 320, 330 discussed above.

By using paths, which are relatively narrow, the inner part, indicated by a dashed circle, of semiconductor die 400 can be probed for die cracks.

In the above, the present invention has been explained using detailed embodiments thereof. However, the present invention is not limited to these embodiments. Rather, several modifications are possible without departing from the scope of the present invention, which is defined by the appended claims and their equivalents.

What is claimed is:

1. A die crack detection system, comprising:
a semiconductor device comprising:
a semiconductor body in or on which at least one component is integrated and that comprises a conductive region;
an electrically insulating layer arranged on the conductive region;
a first conductive trace arranged on the electrically insulating layer;
a first contact that is electrically connected to the first conductive trace; and
a second contact that is electrically connected to the conductive region; and
a measuring unit,
wherein the first conductive trace, the electrically insulating layer, and the conductive region form a capacitor,
wherein the die crack detection system is operable in a first mode:
in which the measuring unit is configured to output a first electrical signal to the first contact or the second contact; and
to determine whether at least one die crack exists in the semiconductor body based on I-V characteristics corresponding to the outputted first electrical signal,
wherein the first contact is arranged at an end of the first conductive trace,
wherein the first conductive trace comprises a fifth contact arranged at an opposing end of the first conductive trace, and
wherein a shape of the second conductive trace is identical to a shape of the first conductive trace.

2. The die crack detection system according to claim 1, wherein the second contact is configured to be electrically grounded when operating in the first mode.

3. The die crack detection system according to claim 1, wherein the first electrical signal is a voltage signal, and wherein the measuring unit is configured to determine that at least one die crack exists when a current through the first contact or the second contact exceeds a first threshold.

4. The die crack detection system according to claim 3, wherein the measuring unit is configured to measure the current through the first contact or the second contact a predetermined amount of time after applying the voltage signal to avoid or limit measuring a current that is associated with charging a capacitance formed between the first conductive trace and the conductive region.

5. The die crack detection system according to claim 1,
wherein the at least one component is a metal-oxide-semiconductor field-effect transistor (MOSFET), a metal-insulator-semiconductor field-effect transistor (MISFET), or a metal-insulator-metal capacitor, and
wherein the electrically insulating layer is:
formed by an electrically insulating layer that is also arranged in between a gate and the semiconductor body of the MOSFET or MISFET; or
formed by the insulator of the metal-insulator-metal capacitor.

6. The die crack detection system according to claim 1, wherein:
a thickness of the electrically insulating layer is between 2 nm and 200 nm; or
the electrically insulating layer comprises silicon oxide, silicon dioxide, silicon nitride, or silicon oxynitride.

7. The die crack detection system according to claim 1, wherein a width of the first conductive trace is between 0.1 micrometers and 50 micrometers.

8. The die crack detection system according to claim 1, wherein the first conductive trace is made from polysilicon or metal.

9. The die crack detection system according to claim 1, further comprising a second conductive trace,
wherein the second conductive trace has a third contact and a fourth contact arranged on opposite ends of the second conductive trace,
wherein the die crack detection system is further operable in a second mode, and
wherein the measuring unit is configured to, when the die crack detection system operates in the second mode:
output a second electrical signal to the third contact or the fourth contact; and
determine whether at least one die crack exists in the semiconductor body based on I-V characteristics corresponding to the outputted second electrical signal.

10. The die crack detection system according to claim 9,
wherein the second electrical signal is a voltage signal,
wherein the measuring unit is configured to determine, when the die crack detection system operates in the second mode, that at least one die crack exists when a current through the third contact or the fourth contact is below a second threshold, and
wherein the measuring unit is configured to measure the current through the third contact or the fourth contact a predetermined amount of time after applying the voltage signal to avoid or limit measuring a current that is associated with charging a capacitance formed between the second conductive trace and the conductive region.

11. The die crack detection system according to claim 9, wherein the die crack detection system is further operable in a third mode,
wherein the measuring unit is configured to, when the die crack detection system operates in the third mode:
output a third electrical signal to the first contact or the second contact;
output a fourth electrical signal to the third contact or the fourth contact; and
determine whether at least one die crack exists in the semiconductor body based on:
I-V characteristics corresponding to the outputted third electrical signal and associated with the first electrical contact and the second electrical contact; and
I-V characteristics corresponding to the outputted fourth electrical signal and associated with the third electrical contact and the fourth electrical contact.

12. The die crack detection system according to claim 11, wherein the measuring unit is integrated in the semiconductor body, said measuring unit having:
an input terminal for receiving a control signal for enabling the die crack detection system to operate in the first mode, the second mode, or the third mode; and
an output terminal for outputting a signal indicative for whether the measuring unit has determined that at least one die crack in the semiconductor body exists or not.

13. The die crack detection system according to claim 9,
wherein the second conductive trace forms an elongated thin film resistor,
wherein the second conductive trace is made from a metal, and
wherein the second conductive trace is arranged directly above the first conductive trace.

14. The die crack detection system according to claim 1, wherein the first conductive trace and the second conductive trace are formed as a combined path.

15. The die crack detection system according to claim 1,
wherein:
the first contact and the third contact form a first unit; or
the fourth contact and the fifth contact form a second unit,
wherein the first unit is identical to the second unit, and
wherein the first unit and the second unit each comprise:
a contact pad;
a first trace contact part that is electrically connected to the first conductive trace;
a second trace contact part that is electrically connected to the second conductive trace; and
at least one of:
one or more first vias connecting the first trace contact part to the contact pad;
one or more second vias connecting the second trace contact part to the contact pad; or
one or more ground vias connecting the contact pad, at least during operation, to ground.

16. The die crack detection system according to claim 15, wherein a width of the second conductive trace lies is between 0.1 micrometers and 50 micrometers.

17. The die crack detection system according to claim 1,
wherein the semiconductor body comprises a substrate on which an epitaxial layer is arranged,
wherein the conductive region is formed within the epitaxial layer,
wherein the second contact is formed on or by a backside of the substrate, and
wherein the substrate is a conductive substrate.

18. The die crack detection system according to claim 1, wherein a thickness of the semiconductor body is between 25 micrometers and 1000 micrometers.

19. The die crack detection system according to claim 1, wherein the semiconductor device is a semiconductor die or a semiconductor wafer.

20. A semiconductor device comprising:
a semiconductor body in or on which at least one component is integrated and that comprises a conductive region;
an electrically insulating layer arranged on the conductive region;
a first conductive trace arranged on the electrically insulating layer;
a first contact that is electrically connected to the first conductive trace; and
a second contact that is electrically connected to the conductive region,
wherein the first conductive trace, the electrically insulating layer, and the conductive region form a capacitor,
wherein the semiconductor device is a component of a die crack detection system,
wherein the die crack detection system comprises a measuring unit,
wherein the die crack detection system is operable in a first mode:
in which the measuring unit is configured to output a first electrical signal to the first contact or the second contact; and
to determine whether at least one die crack exists in the semiconductor body based on I-V characteristics corresponding to the outputted first electrical signal,
wherein the first contact is arranged at an end of the first conductive trace,
wherein the first conductive trace comprises a fifth contact arranged at an opposing end of the first conductive trace, and
wherein a shape of the second conductive trace is identical to a shape of the first conductive trace.
